(19) United States
(12) Patent Application Publication
(10) Pub. No.: US 2018/0010224 A1
(43) Pub. Date: Jan. 11, 2018

(54) METHOD FOR APPLYING A METAL PROTECTIVE COATING TO A SURFACE OF A STEEL PRODUCT

(71) Applicant: THYSSENKRUPP STEEL EUROPE AG, Duisburg (DE)

(72) Inventors: Martin NORDEN, Essen (DE); Ingo KLÜPPEL, Bochum (DE); Miroslaw GIZA, Schwerte (DE)

(73) Assignee: THYSSENKRUPP STEEL EUROPE AG, Duisburg (DE)

(21) Appl. No.: 15/547,120

(22) PCT Filed: Nov. 10, 2015
(86) PCT No.: PCT/EP2015/076207

§ 371 Date: Jul. 28, 2017

(30) Foreign Application Priority Data
Jan. 29, 2015 (DE) 10 2015 101 312.6

(51) Int. Cl. C23C 2/02; C23C 2/26; C23C 2/06; C23C 14/10; C23C 2/40

(52) U.S. Cl. CPC C23C 2/02; C23C 14/10; C23C 2/40; C23C 4/129; C23C 2/06; C23C 2/26

(57) ABSTRACT

A method for applying a metallic protective coating to a surface of a steel product, where another surface is to remain free from the metallic protective coating, may involve applying the metallic protective coating by hot dip coating in a hot dip coating bath. A preliminary coating may be applied to the surface that is to remain free from the metallic protective coating prior to the hot dip coating. The preliminary coating may include SiO₂ and may prevent the metallic protective coating from adhering to the intended surface during hot dip coating. Thus one surface of a steel product may be provided with a metallic protective coating, and another surface of the steel product may be kept free from the protective coating, all with a minimum of cost and complexity and with optimized resource economics. Further, the preliminary coating, deposited from a gas phase to that surface of the steel product that is to be kept free from the metallic protective coating, may be a layer that includes amorphous silicon dioxide and has a layer thickness of 0.5-500 nm.”

The invention relates to a method for applying a metallic protective coating to a surface of a steel product, where at least one other surface is to remain free from the metallic protective coating, the metallic protective coating being applied by hot dip coating in a hot dip coating bath, with that surface that is to remain free from the metallic protective coating being provided, prior to the hot dip coating, with a preliminary coating which consists of SiO₂ and which during hot dip coating prevents the metallic protective coating adhering to the surface in question.

Application of a metallic protective coating is an established means of protecting from corrosion those steel products whose composition puts them fundamentally at risk from corrosion. For many end uses, it is sufficient in this case, and desirable from the standpoint of cost-effective and resource-economical production and processing, to provide the protective coating only to those faces or that section of face which is exposed to corrosive attack in practical service.

One cost-effective means established within industrial practice for applying a metallic protective coating to a steel product is that of hot dip coating.

With hot dip coating, the product to be coated, piecewise or in continuous operation, passes through a hot dip coating bath which is formed of a molten metal that forms the protective coating, or of a molten metal alloy. A heat treatment is usually included upstream of the passage through the hot dip coating bath. The aim of such treatment is to condition the particular steel substrate for coating, and activate its surface, in such a way as on the one hand to achieve optimized physical properties and on the other hand to ensure optimum wetting and adhesion of the coating on the steel substrate.

Particularly well-established are protective coatings based on zinc or aluminum, which in addition to their principal constituents may each comprise further alloying elements in order to set the properties desired for the respective coating.

In the industrial sphere, linear, flat steel products, which typically are rolled products formed from a steel substrate, such as steel sheets or steel strips, or blanks or bars and the like obtained from them, can be economically provided with a metallic anticorrosion coating by means of hot dip coating processes completed in a continuous-run operation. Conversely, steel components formed of or composed of flat steel products, and intended to receive a protective coating following their production, are generally hot dip coated by piecewise immersion into the respective melt bath. In cases where hot dip coating is employed but only a particular area of the steel product is to be provided with the protective coating, however, the area which is to be kept free from the coating must be prepared in each case in such a way that the coating metal does not adhere to this area when the product is immersed into the melt bath.

DE 26 09 968 Al proposed for this purpose, prior to the hot dip coating of a flat steel product with a protective Zn coating, applying a silicone resin to that side of the flat steel product that is not to be coated with zinc. Following application of the silicone resin, the flat steel product is brought to 300-800° C. in an oxidizing atmosphere in order to bake the silicone resin layer into the steel substrate. The aim of this baking operation is to form a covering layer of SiO₂ over the area that is not to be coated. The flat steel product having received such preliminary coating is subsequently subjected to heat treatment under a reducing atmosphere and finally is introduced into a zinc melt bath, where those regions of the surface not having undergone preliminary coating are galvanized. The successful one-sided galvanizing is said here to depend critically on the fact that during annealing under the reducing atmosphere, the area of the flat steel product that is not to be coated is covered with a sufficiently thick SiO₂ film which prevents activation of the area not to be coated, and that at the same time forms a barrier to contact between the area not to be coated and the molten coating metal. To ensure sufficient thickness of the SiO₂ film, the coat weight with which the silicone resin is applied to the steel substrate is in the range of 0.5-50 g/m²; in the practical trialing of the known process, coat weights of 0.7-47 g/m² were provided.

Given the fact that in spite of these measures, it is in practice not possible with the known process to prevent wetting by molten coating metal of that area of the flat steel product that is not to be coated, the known process additionally envisages brushing off the silicone resin-coated surface of the steel strip after it has left the zinc bath, in order first to remove possible accumulations of the coating material and on the other hand to remove the silicone resin coating itself.

Against the background of the prior art as elucidated above, the problem which emerged was that of developing a method allowing at least one defined area of a steel product to be provided by hot dip coating with a metallic protective coating, and at least one other area of the flat steel product to be kept free from the protective coating, all with minimized cost and complexity and with optimized economy of resources.

This problem has been solved by the method specified in claim 1.

Advantageous embodiments of the invention are specified in the dependent claims and are elucidated in detail below along with the general concept of the invention.

In agreement with the prior art elucidated above, the method of the invention also involves applying the metallic protective coating to a surface of a steel product, where at least one other surface is to remain free from the metallic protective coating, the metallic protective coating being applied by hot dip coating in a hot dip coating bath, with that surface that is to remain free from the metallic protective coating being provided, prior to the hot dip coating, with a preliminary coating which consists of SiO₂ and which during hot dip coating prevents the metallic protective coating adhering to the surface in question.

In accordance with the invention, the preliminary coating deposited from the gas phase onto that surface of the steel product that is to be kept free from the metallic protective coating is a layer which consists of amorphous silicon dioxide and has a layer thickness of 0.5-500 nm.

The invention therefore provides a method for producing a single-sidedly hot-dip-enhanced flat steel product that does not require use of a silicone resin from which a comparably thick SiO₂ film is formed, via a separate baking and oxidizing step, on that area of the steel product that is to be kept free from the protective coating. Instead, the invention envisages using a suitable deposition process to deposit a thin SiO₂ layer directly and without intermediate support on that area of the steel product that is to be protected from contact with the coating melt in the course of hot dip coating. For this purpose, silicon-organic compounds can be used in the particular deposition operation, that are not silicone resins as used in the case of the above-elucidated prior art.

Since the silicon-containing compounds forming the preliminary coating are deposited directly onto the steel substrate, the operating step of baking is gone in the case of the method of the invention. Furthermore, the targeted deposition of the SiO₂ layer from the gas phase, as envisaged in accordance with the invention, has the advantage over modes of coating where the SiO₂ layer is formed from the liquid phase that deposition from the gas phase is independent of costly and inconvenient processing baths, requires much less volume of ingredients, and allows minimized layer thicknesses in the nanometer range. All of this, when the method of the invention is employed, leads to a significant reduction in the formation of wastes and, in association with that, to a level of environmental pollution which is likewise significantly reduced relative to the known processes.

The preliminary coating of that area of the steel product that is to be kept free from the metallic protective coating may take place by means of known processes which are established in the art. Depending on the particular starting product and on the manner in which the further processing steps are completed, it may be useful here to deposit the preliminary coating piecewise, in a discontinuous procedure, on the steel product, or to perform the deposition in a continuous procedure. Deposition of the preliminary coating in a continuous procedure onto the area not to be coated is appropriate, for example, when the steel product is a flat steel product, especially a steel strip. This is the case more particularly when the preliminary coating is incorporated into a hot dip coating operation which, from the preliminary coating through to passage through the hot dip coating bath, is undertaken overall in a continuous run.

The deposition of the preliminary coating that is envisaged in accordance with the invention may take place for example by means of flame pyrolysis. Layers generated by flame pyrolysis serve generally as promoters of adhesion between inorganic substrates and organic coatings, especially between metallic substrates and organic coatings. Where a preliminary coating of a type in accordance with the invention is applied by means of flame pyrolysis to the respective steel substrate, it is found, surprisingly, that in spite of the minimized layer thicknesses there is no wetting of that particular area of the steel substrate that is to be kept free from the protective coating. The flame pyrolysis process is elucidated in detail, for example, in the dissertation by Dr. Bernhard Schinkinger, “Layer-analysis and electrochemical studies into the deposition of thin SiO₂ and organosilane layers on galvanized steel”, published under the following URL: http://www-brs.ub.ruhr-uni-bochum.de/netahtml/HSS/Diss/SchinkingerBernhard/diss.pdf (see also URL http://www-brs.ub.ruhr-uni-bochum.de/netahtml/HSS/Diss/SchinkingerBernhard/).

In relation to the present invention, for coating by means of flame pyrolysis, a silicon-organic precursor can be subjected to flame-pyrolytic decomposition in a combustible gas or gas mixture (e.g., air/propane or air/butane), with a precursor flow rate of 10-5000 ml/min and a vaporizer temperature of −50° C. to +100° C. (e.g., hexamethyldisiloxane “HMDSO”), and is thereby deposited on the metal sheet passed through the burner flame. By modifying the burner distance, the coating speed, the gas mixture and composition, and the arrangement of the burners, it is possible to vary the thickness and properties of the layer deposited, in order to set the optimum properties. For this purpose, for example, the burner distance can be varied in the range of 0.5-10 cm, and the coating speed in the range of 1-300 m/min. Propane or butane may be used as combustible gas. If, when using one of these combustible gases, a combustible gas mixture formed from gas and air is employed, the fraction of the combustible gas in the mixture may be 10-100 vol %. In other words, the possibility of operating with pure gas, with no admixing of air, is also encompassed here in the sense of the invention by the term “combustible gas mixture”. The coating outcome can also be influenced positively via the arrangement and number of the burners used for the flame pyrolysis. In the case of a flame pyrolysis taking place in continuous operation, it may be useful to provide up to 10 burners in the direction through which the steel substrate to be coated passes successive burners in series. Because of the good adhesion properties, there is no need for pretreatment of the steel substrate.

For the deposition of the preliminary coating provided in accordance with the invention, it is also possible to use known deposition processes of chemical (CVD) or physical (PVD) type that are available in the prior art (“CVD”=Chemical Vapor Deposition; “PVD”=Physical Vapor Deposition).

Having proven appropriate here in the course of practical trialing was the deposition of the preliminary coating, envisaged in accordance with the invention, by means of hollow cathode glow discharge. By means of this process, that is also known in the art as “PE-CVD”, it is possible to produce compact, silicon-containing layers, known as plasma polymer (“PP”) layers. In the case of the SHC process, coating is carried out by decomposition of a mixture of a carrier gas (e.g., a mixture of oxygen and argon) and a silicon-organic precursor in a low-pressure plasma, and by deposition thereof on the metal sheet. A detailed explanation of this process is found in the dissertation by Dr. Krasimir Nikolov, “Studies on the plasma-enhanced deposition of layers on fine steel sheet at low pressure and high rates”, Shaker Verlag GmbH, March 2008, ISBN 978-3-8322-7068-1. An advantage of this approach lies in the much lower gas consumption because of the reduced operating pressure. In this case it is possible to optimize the thickness and the properties of the layer deposited, by altering the coating parameters, such as in-coupled electrical power, gas composition, and gas flow rate. In the case of a coating unit that is used in the art, the in-coupled electrical power is 0.3 kW. As carrier gas, 40 sccm of argon in 400 sccm of oxygen are mixed with one another and 40 sccm of HMDSO are admixed as precursor to these carrier gas components.

On account of its high thermal stability, the preliminary coating deposited in accordance with the invention is still present after hot dip coating on the area of the steel product that is then free from the protective coating. Depending on the particular end use of the steel product, the preliminary coating may remain on the area not provided with the metallic coating. Its effect there is likewise that of inhibiting corrosion, and, in the event the area provided with the preliminary coating of the invention is to be painted or otherwise organically coated, it also forms an adhesion base by which the adhesion of the respective coating on the steel substrate is enhanced.

If, on the other hand, the preliminary coating is to be removed, after the hot dip coating procedure, from the area of the steel product that in that case has remained uncoated, this may be done using the known mechanical methods, such as brushing, for example, or chemical methods, such as a hydrofluoric acid treatment conducted in a manner of conventional pickling, for example.

With the methods of the invention, wetting of that area to be kept free from the protective coating by the melt of the melt bath in the course of hot dip coating can be prevented in an operationally reliable manner, with the layer thickness of the preliminary coating minimized at the same time. It has emerged here, surprisingly, that the preliminary coating deposited in accordance with the invention from the gas phase on the steel substrate, in spite of the low layer thickness of this coating, is sufficiently impervious as to reliably prevent adhesion of melt on the area to be kept free. This is still ensured even when the thickness of the preliminary coating is limited to 200 nm, more particularly 100 nm, with layer thicknesses of at least 2 nm, more particularly of at least 10 nm, having proven in practice to be particularly effective.

The preliminary coating acquired in accordance with the invention and deposited from the gas phase on that area of the respective steel product that is to be kept free from the metallic protective coating, proves to have a temperature stability such that the steel product preliminarily coated therewith is able without problems to withstand the heat-treatment steps that are customarily provided in preparation for hot dip coating.

Accordingly, the steel product, following application of the preliminary coating and before it passes through the hot dip coating bath, can be annealed in a continuous run at an annealing temperature of 700-900° C. under an annealing atmosphere which contains 0.5-10 vol % of H₂, more particularly 1-5 vol % of H₂, and as the balance nitrogen plus unavoidable impurities and which has a dew point of −50° C. to −10° C., more particularly −45° C. to −5° C., for an annealing time of 6-300 s. The heating rate at which the steel product is heated in each case to the annealing temperature is typically 0.5-35 K/s here.

In order to optimize further the nature of the area to be provided with the coating, in terms of effective adhesion of the coating applied to the steel substrate in the subsequent hot dip coating step, the respective steel product, after the annealing and before the application of the hot dip coating, can be subjected to an overaging treatment in which it is held for a time of 6-180 s in the temperature range of 400-520° C.

For entry into the melt bath, finally, the steel product may be brought to a bath entry temperature which is within a range whose lower limit is the temperature of the melt bath −30° C. and whose upper limit is the temperature of the melt bath +30° C.

Typical layer thicknesses of a protective coating generated on the respective steel substrate by hot dip coating are 7.5 μm ±3.5 μm.

The method of the invention is especially suitable for the processing of flat steel products which are hot dip coated in a continuous run. The term “flat steel product” embraces all rolled products whose length is very much greater than their thickness. These include, as mentioned, steel strips and steel sheets, and also bars and blanks obtained from them. A particular advantage of the invention is that a flat steel product in the form of hot strip or, after cold rolling, in the roll-hardened state can be subjected to the method of the invention.

More particularly, the steel products to be provided in accordance with the invention with a metallic protective coating may consist of thin sheets. By these are meant steel strips or steel sheets having a thickness of less than 3 mm, which can be cold-formed in the cold-rolled or hot-rolled state to form a component. An overview of flat steel products of the type in question that are typically envisaged as thin sheets for cold forming is provided by DIN EN 10130. The steels suitable for the steel substrate of steel products processed in accordance with the invention may specifically be bracketed together under alloying protocol whereby the steels in question consist of (in weight %) up to 16% Mn, up to 3% Al, up to 2% Si, up to 0.3 C, up to 0.5% Ti, up to 1% Ni, up to 0.5% Nb, and up to 2% Cr, with the balance being iron and unavoidable impurities.

The success comes about especially when the steel product, for protection from corrosion, is to be coated by hot dip coating with a protective coating composed of zinc or a zinc alloy. Zn coatings of this kind typically contain up to 5 wt % of Al, up to 2.0 wt % of Mg, up to 0.2 wt % of Fe, and in total up to 10 wt % of other constituents, such as Mn and Si, which may be added to the Zn coating in a known way in order to adjust its properties, the balance being zinc and impurities unavoidable as a result of the production process.

Typical layer thicknesses of the metallic protective coatings applied in accordance with the invention are in the range of 3-30 μm.

When content information is stated here for metal alloys, it is based in each case on the weight, unless expressly indicated otherwise. Any information given with regard to the composition of an atmosphere is based in each case on the volume of the atmosphere, unless expressly indicated otherwise.

The invention is elucidated in more detail below with working examples.

Eight steel strip samples P1-P8 were provided, consisting of steels having the compositions reported in table 3.

Samples P1-P8 were each to be provided on the surface of one side thereof with a protective Zn coating. The surface on the other side of the samples, in contrast, the side opposite to the surface to be provided with the protective coating, was to remain free from the metallic protective coating.

A preliminary SiO₂ coating was deposited by flame pyrolysis under atmospheric pressure to that surface of samples P1-P4 that was to be kept free from the coating. For this purpose, in a silane vaporizer in a flame pyrolysis apparatus, at a vaporization temperature of 40° C., hexamethyldisiloxane (“HMDSO”) was evaporated in each case as silicon-organic precursor. The vaporized HMDSO was introduced at a volume flow rate of 550 ml/min into the burner flame, which was 5 cm wide and was delivered by a burner through combustion of a gas mixture formed of propane and air in a volume ratio of 1:10; the HMDSO was pyrolytically decomposed by the heat of combustion and deposited on that surface of samples P1-P4 that was to be provided with the preliminary SiO₂ coating, said surface being passed below the burner area with a conveying speed of 30 m/min.

The number Z of passages completed by samples P1-P4 through the flame pyrolysis apparatus, the layer thickness SD of the preliminary SiO₂ coating achieved as a result in each case, and the coat weight AG achieved in each case for the preliminary SiO₂ coating are reported in table 1.

In the case of samples P5-P8, in contrast, a preliminary SiO₂ coating was deposited in a PE-CVD apparatus onto the surface to be kept free from the coating. For this purpose, HMDSO vaporized at 60° C. was deposited on the respective surface at a volume flow rate of 40 standard cubic centimeters per minute (“sccm”), after having been mixed with argon, which served as carried gas and was likewise supplied at a volume rate of 40 sccm, and admixed with oxygen, which was supplied at a volume flow rate of 400 sccm. The electrical power of the PE-CVD apparatus was 0.3 kW at a frequency of 350 kHz. A maximum deposition rate of 4 nm/s was achieved.

The coating time TB observed in each case, the layer thickness SD achieved in each case for the preliminary SiO₂ coating, and the coat weight AG achieved in each case for the preliminary SiO₂ coating are reported in table 2.

Following the deposition of the preliminary coating, samples P1-P8 underwent a heat treatment, in a continuous run, in which they were first heated at a heating rate of 10 K/s±1 K/s, to a hold temperature of 800° C.±10° C., at which they were held for 60 s±1 s. The annealing atmosphere during the annealing consisted of 5 vol % of H₂, with the balance made up to N₂ and also technically unavoidable impurities. The dew point of the annealing atmosphere was −30° C.

Samples P1-P8 were subsequently cooled, in each case at a cooling rate of 7 K/s±1 K/s, to an overaging temperature of 470° C.±10° C., at which they were held for 30 s±1 s.

The overaging temperature corresponded to the bath entry temperature at which samples P1-P8 ran subsequently into a zinc melt bath which apart from unavoidable impurities contained no other constituents. The temperature of the melt bath was 465° C.±5° C.

The time required for passage through the melt bath was 2 s±1 s. Following emergence from the melt bath, each sample surface to be provided with the protective coating had a protective Zn coating whose thickness was the targeted 7 μm±3 μm.

In contrast, the surface provided with the preliminary SiO₂ coating was completely free from the Zn coating. Subsequent removal of adhering Zn was unnecessary.

TABLE 1

| | | SD | AG |
|---|---|---|---|
| Sample | Z | [nm] | [mg/m²] |
| P1 | 1 | 2 | 4 |
| P2 | 8 | 10 | 22 |
| P3 | 16 | 20 | 44 |
| P4 | 32 | 50 | 110 |

TABLE 2

| | TB | SD | AG |
|---|---|---|---|
| Sample | [s] | [nm] | [mg/m²] |
| P5 | 7 | 25 | 55 |
| P6 | 14 | 50 | 110 |
| P7 | 35 | 130 | 285 |
| P8 | 120 | 430 | 942 |

TABLE 3

| Sample | C | Si | Mn | P | Al | Cr | Mo | Ti | Nb |
|---|---|---|---|---|---|---|---|---|---|
| 1 | 0.002 | 0.02 | 0.1 | 0.005 | 0.03 | 0.03 | 0.001 | 0.050 | 0.001 |
| 2 | 0.002 | 0.10 | 0.40 | 0.04 | 0.02 | 0.03 | 0.001 | 0.040 | 0.020 |
| 3 | 0.05 | 0.10 | 1.40 | 0.01 | 0.02 | 0.50 | 0.001 | 0.020 | 0.001 |
| 4 | 0.12 | 0.10 | 1.70 | 0.01 | 1.30 | 0.50 | 0.100 | 0.001 | 0.020 |
| 5 | 0.20 | 0.10 | 1.70 | 0.01 | 1.50 | 0.10 | 0.100 | 0.001 | 0.001 |
| 6 | 0.16 | 1.50 | 1.60 | 0.01 | 0.05 | 0.05 | 0.001 | 0.001 | 0.001 |
| 7 | 0.15 | 0.25 | 1.80 | 0.01 | 0.70 | 0.70 | 0.001 | 0.020 | 0.030 |
| 8 | 0.22 | 1.8 | 15.6 | 0.04 | 2.5 | 0.8 | 0.01 | 0.001 | 0.030 |

Amounts in weight %, balance Fe and unavoidable impurities

1-15. (canceled)

16. A method for applying a metallic protective coating to a first surface of a steel product, wherein a second surface of the steel product is to remain free from the metallic protective coating, the method comprising:
applying a preliminary coating comprising SiO2 to the second surface of the steel product, the preliminary coating for preventing the metallic protective coating from adhering to the second surface, wherein the preliminary coating is deposited from a gas phase to the second surface, wherein the preliminary coating applied to the second surface is a layer that comprises amorphous silicon dioxide and has a layer thickness of 0.5-500 nm; and
applying the metallic protective coating by hot dip coating in a hot dip coating bath after the preliminary coating has been applied to the second surface of the steel product.

17. The method of claim 16 comprising depositing the preliminary coating by flame pyrolysis.

18. The method of claim 16 comprising depositing the preliminary coating by way of a chemical or physical vapor deposition process.

19. The method of claim 16 wherein the layer thickness of the layer of the preliminary coating applied to the second surface is at most 200 nm.

20. The method of claim 19 wherein the layer thickness of the layer of the preliminary coating applied to the second surface is at most 100 nm.

21. The method of claim 16 wherein the layer thickness of the layer of the preliminary coating applied to the second surface is at least 2 nm.

22. The method of claim 16 wherein the layer thickness of the layer of the preliminary coating applied to the second surface is at least 10 nm.

23. The method of claim 16 further comprising annealing the steel product in a continuous run at an annealing temperature of 700-900° C. under an annealing atmosphere that contains 0.5-10% by volume H₂ and as a balance nitrogen and unavoidable impurities, the annealing atmosphere having a dew point of −50° C. to −10° C. for an annealing time of 6-300 seconds, wherein the annealing of the steel product occurs after application of the preliminary coating but before the steel product passes through the hot dip coating bath.

24. The method of claim 23 further comprising subjecting the steel product to overaging treatment in which the steel product is held for 6-180 seconds in a temperature range of 400-520° C., wherein the steel product is subjected to the overaging treatment after the annealing but before the hot dip coating.

25. The method of claim 16 wherein for entry into the hot dip coating bath the method comprises bringing the steel product to a bath entry temperature within a range whose lower limit is a temperature of a melt bath −30° C. and whose upper limit is a temperature of a melt bath +30° C.

26. The method of claim 16 wherein the steel product is a flat steel product whose steel substrate is formed by a thin sheet.

27. The method of claim 26 further comprising providing the flat steel product in a roll-hardened state or as hot strip for hot dip coating.

28. The method of claim 16 wherein the application of the preliminary coating and the application of the metallic protective coating are performed in a continuous-run operation.

29. The method of claim 16 further comprising removing the preliminary coating from the second surface after the hot dip coating of the steel product.

30. The method of claim 16 wherein the metallic protective coating comprises Zn and unavoidable impurities.

31. The method of claim 30 wherein the metallic protective coating further comprises up to 5% by weight of Al, up to 2.0% by weight of Mg, up to 0.2% by weight of Fe, and in total up to 10% by weight of one or more of Mn or Si.
